(19) United States
(12) Patent Application Publication
(10) Pub. No.: US 2025/0022737 A1
(43) Pub. Date: Jan. 16, 2025

(54) SUBSTRATE PROCESSING APPARATUS

(71) Applicant: SEMES CO., LTD., Cheonan-si (KR)

(72) Inventors: Taewoong SEO, Cheonan-si (KR); Hoshin KANG, Asan-si (KR); Yeonsu CHOI, Cheonan-si (KR); Songhae JEONG, Chungju-si (KR)

(73) Assignee: SEMES CO., LTD., Cheonan-si (KR)

(21) Appl. No.: 18/767,451

(22) Filed: Jul. 9, 2024

(30) Foreign Application Priority Data
Jul. 11, 2023 (KR) 10-2023-0089544

(51) Int. Cl. H01L 21/677; H01L 21/67

(52) U.S. Cl. CPC H01L 21/67745; H01L 21/67155

(57) ABSTRACT

A substrate processing apparatus includes first and second processing modules, first and second transfer modules for queuing and transferring a first substrate, which can only be fed into the first processing module, a second substrate, which can only be fed into the second processing module, respectively, and a sequence adjustment unit. The first or second transfer module can be used to queue and transfer a third substrate that can be loaded into both the first and second processing modules. The sequence adjustment unit adjusts the process sequence such that at least some of the first, second, and third substrates, which are junior to a substrate being processed in the process sequence, are prioritized for queuing and transferring using the first or second transfer module that is in an idle state or about to become an idle state.

### CROSS-RELATED APPLICATION

This application claims priority under 35 USC § 119 to Korean Patent Application No. 10-2023-0089544, filed on Jul. 11, 2023 in the Korean Intellectual Property Office (KIPO), the contents of which are herein incorporated by reference in their entirety.

### BACKGROUND

### 1. Field

The present invention relates to a substrate processing apparatus. More specifically, the invention relates to a technology for improving the utilization of manufacturing processing modules by optimizing the processing priority of substrate lots.

### 2. Description of the Related Art

In the manufacture of integrated circuit devices such as semiconductor devices, display devices, and the like, there may be frequent queuing and transferring of substrates into and out of processing modules where processing processes are performed. In recent years, substrate processing apparatuses used in the manufacture of integrated circuit devices may be configured to have a structure comprising at least two processing modules for efficiency in the order of queuing and transferring substrates, efficiency in device self-control, and the like.

The processing modules may be arranged to have a predominantly multi-stage batch structure, each of which may be equipped to perform a different process. However, conventionally, the queuing and transferring of the substrates to the above processing modules may be arranged to be performed only in a predetermined order. As such, if the substrates are queued and transferred to the above processing modules only in a predetermined order, it may cause a decrease in the efficiency of using the substrate processing apparatus.

### SUMMARY

It is an object of the present invention to provide a substrate processing apparatus capable of improving the utilization of a manufacturing facility by queuing and transporting substrates for at least two process modules, not in a predetermined order, but in an optimized prioritized order of work processing based on the availability of the process equipment for the substrates.

A substrate processing apparatus according to exemplary embodiments to accomplish the objectives of the present disclosure includes a processing module unit, a transfer module unit, and a sequence adjustment unit. The processing module unit includes at least a first processing module and a second processing module which are configured to perform different processes on substrates. The transfer module unit includes a first transfer module configured to queue and transfer a first substrate that can only be loaded into the first processing module, and a second transfer module configured to queue and transfer a second substrate that can only be loaded into the second processing module, wherein either the first transfer module or the second transfer module can be used to queue and transfer a third substrate that can be loaded into both the first and second processing modules. The sequence adjustment unit is configured to adjust a process sequence according to a process flow recipe such that at least some of the first substrate, the second substrate, and the third substrate, which are junior to a substrate being processed in the process sequence, are prioritized for queuing and transferring using the first transfer module or the second transfer module that is in an idle state or about to become an idle state.

In exemplary embodiments, when the process sequence according to the process flow recipe is such that the first substrate is queued and transferred first and then the second substrate is queued and transferred by the first transfer module, the sequence adjustment unit may adjust the process sequence such that the queuing and transferring of the second substrate is prioritized using the second transfer module which is in an idle state or about to become an idle state; or when the process sequence according to the process flow recipe is such that the second substrate queued and transferred first and then the first substrate is queued and transferred by the second transfer module, the sequence adjustment unit may adjust the process sequence such that the queuing and transferring of the first substrate is prioritized using the first transfer module which is in an idle state or about to become an idle state.

In exemplary embodiments, when the process sequence according to the process flow recipe is such that the first substrate is queued and transferred by the first transfer module first, or the second substrate is queued and transferred by the second transfer module first, or both the first substrate and the second substrate are queued and transferred by the first transfer module and the second transfer module respectively, queuing and transferring of the third substrate is scheduled to be performed after queuing and transferring of the first substrate, the second substrate, or the first and second substrates are finished, the sequence adjustment unit may adjust the process sequence so that queuing and transferring of the third substrate can be performed preferentially using the first transfer module or the second transfer module that is in an idle state, or the first transfer module or the second transfer module that is about to become an idle state.

In exemplary embodiments, when the process sequence according to the process flow recipe in the first transfer module is such that queuing and transferring of the third substrate is performed after finishing queuing and transferring of the first substrate, the sequence adjustment unit may adjust the process sequence so that queuing and transferring of the third substrate can be performed preferentially by using the second transfer module, and wherein when queuing and transferring of the first substrate is finished by the first transfer module and queuing and transferring of the third substrate is finished by the second transfer module, the sequence adjustment unit may re-adjust the process sequence so that queuing and transferring of the third substrate can be performed preferentially by using the first transfer module.

In exemplary embodiments, when the process sequence according to the process flow recipe in the second transfer module is such that queuing and transferring of the third substrate is performed after finishing queuing and transferring of the second substrate, the sequence adjustment unit may adjust the process sequence so that queuing and transferring of the third substrate by using the first transfer module can be performed preferentially, and wherein when queuing and transferring of the second substrate is finished by the second transfer module and queuing and transferring of the third substrate is finished by the first transfer module, the sequence adjustment unit may re-adjust the process sequence so that queuing and transferring of the third substrate by using the second transfer module can be performed preferentially.

In exemplary embodiments, when the process sequence according to the process flow recipe is such that queuing and transferring of the first substrate is performed by the first transfer module, then queuing and transferring of the third substrate and the second substrate are performed sequentially after the queuing and transferring of the first substrate is finished, the sequence adjustment unit may adjust the process sequence such that queuing and transferring of the third substrate is preferentially performed by the second transfer module; and wherein when the queuing and transferring of the first substrate is finished by the first transfer module and the queuing and transferring of the third substrate is finished by the second transfer module, the sequence adjustment unit may re-adjust the process sequence such that queuing and transferring of the third substrate can be performed by the first transfer module, and queuing and transferring of the second substrate can be performed by the second transfer module.

In exemplary embodiments, when the process sequence according to the process flow recipe is such that queuing and transferring of the second substrate is performed by the second transfer module, then queuing and transferring of the third substrate and the first substrate are performed sequentially after the queuing and transferring of the second substrate is finished, the sequence adjustment unit may adjust the process sequence such that queuing and transferring of the third substrate is preferentially performed by the first transfer module; and wherein when the queuing and transferring of the second substrate is finished by the second transfer module and the queuing and transferring of the third substrate is finished by the first transfer module, the sequence adjustment unit may re-adjust the process sequence such that queuing and transferring of the third substrate can be performed by the second transfer module, and queuing and transferring of the first substrate can be performed by the first transfer module.

In exemplary embodiments, when the process sequence according to the process flow recipe is such that queuing and transferring of the first substrate and the second substrate are performed by the first and second transfer module respectively first, and then queuing and transferring of the third substrate is performed after the queuing and transferring of either the first substrate or the second substrate is finished by either the first transfer module or the second transfer module, the sequence adjustment unit may adjust the process sequence so that queuing and transferring of the third substrate can be preferentially performed by any one out of the first transfer module and the second transfer module, whichever finishes the transferring first.

A substrate processing apparatus according to exemplary embodiments to accomplish the objectives of the present invention include a first processing module, a second processing module, a transfer module unit, and a sequence adjustment unit. The transfer module unit includes a first transfer module configured to queue and transfer a first substrate that can only be loaded into the first processing module, and a second transfer module configured to queue and transfer a second substrate that can only be loaded into the second processing module, wherein either the first transfer module or the second transfer module can be used to queue and transfer a third substrate that can be loaded into both the first and second processing modules. The sequence adjustment unit is configured to adjust a process sequence according to a process flow recipe such that at least some of the first substrate, the second substrate, and the third substrate, which are junior to a substrate being processed in the process sequence, are prioritized for queuing and transferring using the first transfer module or the second transfer module that is in an idle state or about to become an idle state.

In exemplary embodiments, when the process sequence according to the process flow recipe is such that the first substrate is queued and transferred first and then the second substrate is queued and transferred by the first transfer module, the sequence adjustment unit may adjust the process sequence such that the queuing and transferring of the second substrate is prioritized using the second transfer module which is in an idle state or about to become an idle state; or when the process sequence according to the process flow recipe is such that the second substrate queued and transferred first and then the first substrate is queued and transferred by the second transfer module, the sequence adjustment unit may adjust the process sequence such that the queuing and transferring of the first substrate is prioritized using the first transfer module which is in an idle state or about to become an idle state.

In exemplary embodiments, when the process sequence according to the process flow recipe is such that the first substrate is queued and transferred by the first transfer module first, or the second substrate is queued and transferred by the second transfer module first, or both the first substrate and the second substrate are queued and transferred by the first transfer module and the second transfer module respectively, queuing and transferring of the third substrate is scheduled to be performed after queuing and transferring of the first substrate, the second substrate, or the first and second substrates are finished, the sequence adjustment unit may adjust the process sequence so that queuing and transferring of the third substrate can be performed preferentially using the first transfer module or the second transfer module that is in an idle state, or the first transfer module or the second transfer module that is about to become an idle state.

In exemplary embodiments, when the process sequence according to the process flow recipe in the first transfer module is such that queuing and transferring of the third substrate is performed after finishing queuing and transferring of the first substrate, the sequence adjustment unit may adjust the process sequence so that queuing and transferring of the third substrate can be performed preferentially by using the second transfer module, and wherein when queuing and transferring of the first substrate is finished by the first transfer module and queuing and transferring of the third substrate is finished by the second transfer module, the sequence adjustment unit may re-adjust the process sequence so that queuing and transferring of the third substrate can be performed preferentially by using the first transfer module.

In exemplary embodiments, when the process sequence according to the process flow recipe in the second transfer module is such that queuing and transferring of the third substrate is performed after finishing queuing and transferring of the second substrate, the sequence adjustment unit may adjust the process sequence so that queuing and transferring of the third substrate by using the first transfer module can be performed preferentially, and wherein when queuing and transferring of the second substrate is finished by the second transfer module and queuing and transferring of the third substrate is finished by the first transfer module, the sequence adjustment unit may re-adjust the process sequence so that queuing and transferring of the third substrate by using the second transfer module can be performed preferentially.

In exemplary embodiments, when the process sequence according to the process flow recipe is such that queuing and transferring of the first substrate is performed by the first transfer module, then queuing and transferring of the third substrate and the second substrate are performed sequentially after the queuing and transferring of the first substrate is finished, the sequence adjustment unit may adjust the process sequence such that queuing and transferring of the third substrate is preferentially performed by the second transfer module; and wherein when the queuing and transferring of the first substrate is finished by the first transfer module and the queuing and transferring of the third substrate is finished by the second transfer module, the sequence adjustment unit may re-adjust the process sequence such that queuing and transferring of the third substrate can be performed by the first transfer module, and queuing and transferring of the second substrate can be performed by the second transfer module.

In exemplary embodiments, when the process sequence according to the process flow recipe is such that queuing and transferring of the second substrate is performed by the second transfer module, then queuing and transferring of the third substrate and the first substrate are performed sequentially after the queuing and transferring of the second substrate is finished, the sequence adjustment unit may adjust the process sequence such that queuing and transferring of the third substrate is preferentially performed by the first transfer module; and wherein when the queuing and transferring of the second substrate is finished by the second transfer module and the queuing and transferring of the third substrate is finished by the first transfer module, the sequence adjustment unit may re-adjust the process sequence such that queuing and transferring of the third substrate can be performed by the second transfer module, and queuing and transferring of the first substrate can be performed by the first transfer module.

In exemplary embodiments, when the process sequence according to the process flow recipe is such that queuing and transferring of the first substrate and the second substrate are performed by the first and second transfer module respectively first, and then queuing and transferring of the third substrate is performed after the queuing and transferring of either the first substrate or the second substrate is finished by either the first transfer module or the second transfer module, the sequence adjustment unit may adjust the process sequence so that queuing and transferring of the third substrate can be preferentially performed by any one out of the first transfer module and the second transfer module, whichever finishes the transferring first.

Meanwhile, a substrate processing apparatus according to exemplary embodiments to accomplish the objectives of the present invention include a first processing module configured to perform a first treatment process with first process conditions, a second processing module configured to perform a second treatment process with second process conditions, a transfer module unit, and a sequence adjustment unit. The transfer module unit includes a first transfer module configured to queue and transfer a first substrate that can only be loaded into the first processing module, and a second transfer module configured to queue and transfer a second substrate that can only be loaded into the second processing module, wherein either the first transfer module or the second transfer module can be used to queue and transfer a third substrate that can be loaded into both the first and second processing modules. The sequence adjustment unit configured to adjust a process sequence according to a process flow recipe, wherein when the process sequence according to the process flow recipe is such that the first substrate is queued and transferred first and then the second substrate is queued and transferred by the first transfer module, the sequence adjustment unit adjusts the process sequence such that the queuing and transferring of the second substrate is prioritized using the second transfer module which is in an idle state or about to become an idle state; or when the process sequence according to the process flow recipe is such that the second substrate queued and transferred first and then the first substrate is queued and transferred by the second transfer module, the sequence adjustment unit adjusts the process sequence such that the queuing and transferring of the first substrate is prioritized using the first transfer module which is in an idle state or about to become an idle state; or wherein when the process sequence according to the process flow recipe is such that the first substrate is queued and transferred by the first transfer module first, or the second substrate is queued and transferred by the second transfer module first, or both the first substrate and the second substrate are queued and transferred by the first transfer module and the second transfer module respectively, queuing and transferring of the third substrate is scheduled to be performed after queuing and transferring of the first substrate, the second substrate, or the first and second substrates are finished, the sequence adjustment unit adjusts the process sequence so that queuing and transferring of the third substrate can be performed preferentially using the first transfer module or the second transfer module that is in an idle state, or the first transfer module or the second transfer module that is about to become an idle state.

In exemplary embodiments, the first processing module may be configured to perform a first baking process on the first substrate or the third substrate at a first temperature condition, and the second processing module is configured to perform a second baking process on the second substrate or the third substrate at a second temperature condition.

In exemplary embodiments, the sequence adjustment unit may adjust the process sequence so that when the third substrate is subsequently queued and transferred by the first transfer module, the queuing and transferring of the third substrate can be preferentially performed by the second transfer module, and when the third substrate is subsequently queued and transferred by the second transfer module, the queuing and transferring of the third substrate can be preferentially performed by the first transfer module.

In exemplary embodiments, when queuing and transferring of the first substrate is performed by the first transfer module and queuing and transferring of the second substrate is performed by the second transfer module, and the third substrate is subsequently queued in either the first transfer module or the second transfer module, the sequence adjustment unit may adjust the process sequence so that queuing and transferring of the third substrate can be performed by the first transfer module or the second transfer module, whichever finishes the queuing and transferring first.

The substrate processing apparatus according to exemplary embodiments of the present invention can optimize the queuing and transfer of substrates to the processing modules, not in a predetermined order, but in an optimized prioritization based on the availability of the process equipment for the substrates, thereby improving the efficiency of the apparatus use. Furthermore, the invention can reduce the time required for the substrate transfer process, thereby improving the productivity of the manufacturing of integrated circuit devices, in particular display devices.

However, the effects of the present invention are not limited to the above-mentioned effects, and may be extended in various ways without departing from the spirit and scope of the present invention.

### BRIEF DESCRIPTION OF THE DRAWINGS

FIG. 1 is a conceptual diagram schematically illustrating the configuration of a substrate processing apparatus according to an exemplary embodiment of the present invention.

FIG. 2 is a flow diagram illustrating a procedure for optimizing the sequence of jobs in the substrate processing apparatus, according to an exemplary embodiment of the present invention.

FIGS. 3A and 3B are illustrations of states before and after a change in the sequence of jobs in the substrate processing apparatus, according to one other exemplary embodiment of the present invention.

FIGS. 4A and 4B are illustrative drawings of states before and after a change in the sequence of jobs in the substrate processing apparatus, according to another exemplary embodiment of the present invention.

FIGS. 5A and 5B are illustrative drawings of states before and after a change in the sequence of jobs in the substrate processing apparatus, according to still another exemplary embodiment of the present invention.

FIGS. 6A and 6B are illustrative drawings of states before and after a change in the sequence of jobs in the substrate processing apparatus, according to still another exemplary embodiment of the present invention.

FIG. 7 is a flow diagram illustrating a procedure for optimizing the sequence of jobs on substrates based on a determination of which transfer modules are scheduled for termination in the substrate processing apparatus, in accordance with another exemplary embodiment of the present invention.

FIGS. 8A through 8C are illustrative drawings of states before and after a change in the sequence of jobs according to FIG. 7 in the substrate processing apparatus, in accordance with an exemplary embodiment of the present invention.

FIGS. 9A and 9B are illustrative drawings of states before and after a change in job priority according to FIG. 7 in a substrate processing apparatus, in accordance with other exemplary embodiment of the present invention.

FIGS. 10A and 10B are illustrative drawings of states before and after a change in job priority according to FIG. 7 in a substrate processing apparatus, in accordance with another exemplary embodiment of the present invention.

### DESCRIPTION OF EMBODIMENTS

The present invention is subject to various modifications and can take many forms, embodiments of which are described in detail herein. However, this is not intended to limit the invention to any particular disclosed form, and is to be understood to include all modifications, equivalents, or substitutions that fall within the scope of the thought and skill of the present invention. In describing the respective drawings, similar reference numerals have been used for similar components. Terms such as first, second, and the like may be used to describe various components, but the components are not to be limited by the terms. These terms are used solely for the purpose of distinguishing one component from another. The terms used in this application are used to describe particular embodiments only and are not intended to limit the invention. Expressions in the singular include the plural unless the context clearly indicates otherwise. In this application, the terms ‘comprising’ or ‘consisting of’ and the like are intended to designate the presence of the features, numbers, steps, operations, components, parts, or combinations thereof described, and are not to be understood as precluding the possibility of the presence or addition of one or more other features, numbers, steps, operations, components, parts, or combinations thereof.

Unless otherwise defined, all terms used herein, including technical or scientific terms, have the same meaning as commonly understood by one of ordinary skill in the art to which this invention belongs. Such terms, as defined in commonly used dictionaries, shall be construed to have a meaning consistent with their meaning in the context of the relevant art and shall not be construed to have an idealized or unduly formal meaning unless expressly defined in this application.

Exemplary embodiments will be described in more detail below with reference to the accompanying drawings. Identical components in the drawings are designated with the same reference numerals and duplicate descriptions of the same component are omitted.

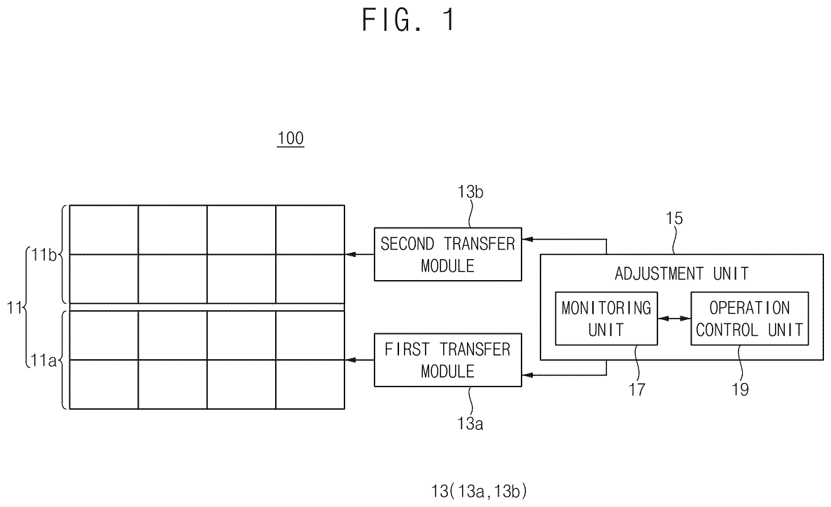

FIG. 1 schematically illustrates the configuration of a substrate processing apparatus according to an exemplary embodiment of the present invention.

Referring to FIG. 1, a substrate processing apparatus 100 according to an exemplary embodiment of the present invention may be for performing a processing targeting a substrate for manufacturing into an integrated circuit device, such as a semiconductor device, a display device, or the like. The substrate processing apparatus 100 may include a processing module unit 11, a transfer module unit 13, a sequence adjustment unit 15, and the like.

The processing module unit 11 may be arranged to provide a processing space for performing a processing on the substrate. The processing module unit 11 may include at least two processing modules, one for one processing and the other for other processing. The processing module unit 11 is not limited to having at least two processing modules. The one processing module may be a first processing module 11a, and the other processing module may be a second processing module 11b. The first processing module 11a and the second processing module 11b may be provided to be arranged in an up-down direction, or alternatively, they may be arranged in a side-to-side direction. The first processing module 11a and the second processing module 11b may be provided to perform different treatment processes. The first processing module 11a may be configured to perform a first treatment process at a first process condition, and the second processing module 11b may be configured to perform a second treatment process at a second process condition. In one example, the first processing module 11a may be configured to perform the first baking process at a first temperature condition (e.g., about 100° C. to 110° C. temperature), and the second processing module 11b may be configured to perform the second baking process at a second temperature condition (e.g., about 110° C. to 120° C. temperature).

The transfer module unit 13 may be provided for queuing and transferring substrates to the processing module unit 11 for feeding. The transfer module unit 13 may include, for example, two transfer modules, a first transfer module 13a for queuing and transferring substrates to one processing module, and a second transfer module 13b for queuing and transferring substrates to the other processing module. The first transfer module 13a may be configured to queue and transfer a first substrate that can only be fed into one of the processing modules, and the second transfer module 13b may be configured to queue and transfer a second substrate that can only be fed into the other processing module. That is, the first transfer module 13a may be configured to queue and transfer the first substrate that can only be fed into the first processing module 11a, and the second transfer module 13b may be configured to queue and transfer the second substrate that can only be fed into the second processing module 11b. And the transfer module unit 13 may be configured to queue and transfer a third substrate that can be loaded into both one processing module and the other processing module. In other words, the queuing and transferring of the third substrate may use either the first transfer module 13a or the second transfer module 13b. Accordingly, the first transfer module 13a may be configured to queue and transfer the first substrate or the third substrate to one of the processing modules, that is, the first processing module 11a, and the second transfer module 13b may be configured to queue and transfer the second substrate or the third substrate to the other of the processing modules, that is, the second processing module 11b.

Here, the first substrate may be subjected to a first treatment process in the first processing module 11a only, and the second substrate may be subjected to a second treatment process in the second processing module 11b only. Further, the third substrate may be subjected to both the first treatment process in the first processing module 11a and the second treatment process in the second processing module 11b. In other words, the first substrate may be subjected to the first treatment process in the first processing module 11a under first process conditions, and the second substrate may be subjected to the second treatment process under second process conditions in the second processing module 11b. And the third substrate may be subjected to the first treatment process in the first processing module 11a under first process conditions and the second treatment process in the second processing module 11b under the second process conditions.

Furthermore, the first to third substrates may be stored in the cassettes for queuing and transferring. Accordingly, the transfer module unit 13 may be configured for queuing and transferring the substrates stored in the cassettes, wherein the first transfer module 13a may be configured for queuing and transferring the first substrate and the third substrate stored in the first cassette and the third cassette, and the second transfer module 13b may be configured for queuing and transferring the second substrate and the third substrate stored in the second cassette and the third cassette.

In the following, the transfer module unit 13 and the processing module unit 11 will be more specifically described. The transfer module unit 13 may be configured to transfer substrates from a prior process to the processing module unit 11, and may have a structure that includes a lot port, an index module, and the like. The lot port may be configured to queue substrates scheduled to be transferred to the processing module unit 11. In one example, the lot port may be a member on which a cassette or the like is placed in which a plurality of substrates are stored. An example of the cassette may be a front opening unified pod (FOUP) or the like having a front door. The index module may be configured to transfer substrates stored in cassettes queued at the lot port to the processing module unit 11. In an example, the index module may comprise a robotic arm or the like.

The processing module unit 11 may be configured to perform a predetermined treatment process on the substrate being transported from the transfer module unit 13. As mentioned above, the processing module unit 11 may comprise the first processing module 11a and the second processing module 11b. The first processing module 11a and the second processing module 11b may be identical in structure, with only the process conditions for the predetermined treatment process being different.

As mentioned, the transfer module unit 13 may include the first transfer module 13a having a first lot port and a first index module, and the second transfer module 13b having a second lot port and a second index module. The processing module unit 11 may include the first processing module 11a for performing, for example, a first baking process on the first substrate or the third substrate at a first temperature condition, and the second processing module 11b for performing, for example, a second baking process on the second substrate or the third substrate at a second temperature condition. The baking processes are an example of processes performed in the processing module unit 11, although other processes may be performed.

And the processing module unit 11 may include a buffer member for temporarily storing the substrate being transferred from the transfer module unit 13. Furthermore, each of the first processing module 11a and the second processing module 11b may be configured as a structure in which multiple processing modules are arranged. Accordingly, each of the first processing module 11a and the second processing module 11b may be provided with its own transfer member in order to transfer the substrate to each of the first processing module 11a and the second processing module 11b of the plurality-arranged structure.

The sequence adjustment unit 15 may be configured to adjust the order in which the substrates start working. For this purpose, the sequence adjustment unit 15 may include a monitoring unit 17 and a computational control unit 19. The monitoring unit 17 may be configured to monitor whether each of the transfer modules 13a, 13b has a waiting substrate, and if so, what type of substrate (each type of substrate has a specific type of treatment process to be performed), and whether each of the processing modules 11a, 11b is currently performing a process operation or is in an idle state with no process operation to perform, and provide the monitoring information to the computational control unit 19. For example, the monitoring unit 17 may perform such monitoring by detecting identification information of the cassette in which the substrate is stored. The computational control unit 19 may be configured to use the monitoring information provided by the monitoring unit 17 as input data, and to execute a job management software program to adjust the job start order of the waiting substrates to an optimal order from time to time or periodically, and to control the process equipment 11, 13 such that the substrates waiting to be processed are rearranged on the transfer modules 13a, 13b according to an adjusted order, and the jobs of treatment processing are performed according to the adjusted order.

The computational control unit 19 may include, for example, a processor, controller, arithmetic logic unit (ALU), digital signal processor, microcomputer, field programmable array (FPA), programmable logic unit (PLU), microprocessor, or any combination of a data processing device capable of executing and responding to instructions and a job management software program, which is a program that may be executed on the data processing device. The program may be implemented in accordance with an algorithm provided by a method according to an exemplary embodiment described below. The program may be stored on one or more computer-readable non-volatile recording media, such as a storage device of, for example, a ROM, flash memory, or the like.

The substrate processing apparatus 100 according to exemplary embodiments of the present invention may be configured to maximize the utilization of the process equipment by adjusting the order in which the substrates waiting in the transfer module unit 13 for input into the processing module 11, i.e., the order in which the substrates are transferred to the processing module 11, based on the availability of process equipment for the substrates, rather than in a predetermined order according to a process flow recipe. When performing a predetermined process on a substrate, performing the process in a predetermined order according to a predetermined flow recipe condition may result in a situation where only some modules (robots/units) of the process equipment are used, and the remaining modules are not utilized for work and are idle. As the process equipment is idle, the utilization rate of the equipment decreases. The substrate processing apparatus 100 can improve the efficiency of the process equipment by increasing the utilization rate of the process equipment by flexibly adjusting the job order in the event that the process equipment becomes idle when the substrates are put into the process in a predetermined work order. That is, the processing apparatus 100 may be configured to adjust the process sequence so that at least some of the first substrate, the second substrate, and the third substrate, which are ranked junior to the substrate currently being processed in the process sequence according to the process flow recipe, may be prioritized for queuing and transferring using the first transfer module 13a or the second transfer module 13b that is currently in an unused (idle) state or scheduled for end of use.

In performing a predetermined process on the substrates in the substrate processing apparatus 100, it is contemplated that the process sequence is predetermined according to a process flow recipe such that the first substrate is queued in the first transfer module 13a to be transferred to the first processing module 11a, and the second substrate is subsequently queued and transferred. The sequence adjustment unit 15 may monitor the status of the first and second transfer modules 13a, 13b periodically or whenever a predetermined event occurs to analyze whether there is a need to adjust the process sequence. If the analysis determines that it is possible to increase the utilization rate of the process equipment, the current process sequence may be adjusted to a new process sequence. For example, in a situation where the first transfer module 13a is currently in use and the second transfer module 130b is idle, the process sequence may be adjusted such that the queuing and transfer of the second substrate to the second process module 11b is prioritized using the second transfer module 13b, which is not in use (i.e., idle with no substrates to queue and transfer), or is scheduled for end of use (i.e., has no substrates queued for transfer other than the substrate currently being transferred), rather than the first transfer module 13a.

In contrast, when the process sequence is such that a second substrate is queued in the second transfer module 13b to be transferred for performing a process in the second process module 11b, and a first substrate is subsequently queued and transferred, the sequence adjustment unit 15 may be configured to adjust, in order to increase the utilization of the process equipment, the process sequence such that the queuing and transferring of the first substrate may be prioritized for performing the process in the first processing module 11a using the first transfer module 13a identified as not currently in use, or the first transfer module 13a identified as soon to be idle. Furthermore, let's consider a process sequence in which the first transfer module 13a is queuing the first substrate for transferring, the second transfer module 13b is queuing the second substrate for transferring, or both the first transfer module 13a and the second transfer module 13b are queuing the first substrate and the second substrate for transferring and then are scheduled to queue and transfer the third substrate after finishing queuing and transferring the first substrate, the second substrate, or the first and second substrates. In this case, the sequence adjustment unit 15 may adjust the process sequence to prioritize the queuing and transferring of the third substrate using the first transfer module 13a or the second transfer module 13b that is determined not to be currently in use. Alternatively, the sequence adjustment unit 15 may adjust the process sequence to prioritize queuing and transferring of the third substrate using the first transfer module 13a or the second transfer module 13b that is scheduled for end of use.

In the following, embodiments of adjusting the process sequence to prioritize the queuing and transferring of the third substrate using the sequence adjustment unit 15 will be described. First, example embodiments will be described in which the queuing and transferring of the third substrate is prioritized based on the results of a check on the transfer module that is currently in an idle state, i.e., not currently provided for use.

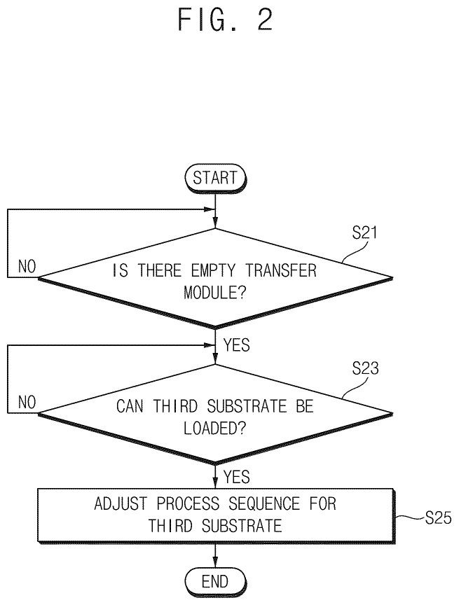

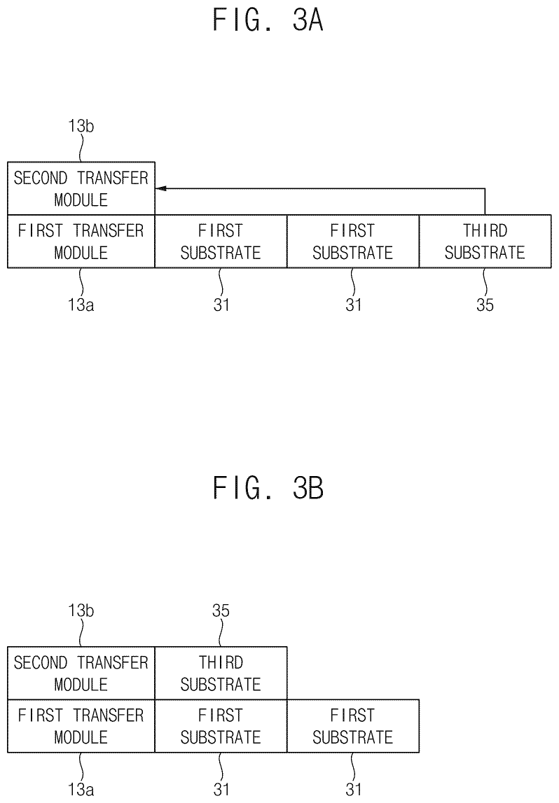

FIG. 2 illustrates a procedure for adjusting the process sequence, or job order in the substrate processing apparatus to an optimal sequence, in accordance with an exemplary embodiment of the present invention. FIGS. 3A through 6B illustrate states before and after adjusting the process sequence in which jobs, or treatment processes are initiated on substrates in the substrate processing apparatus in accordance with exemplary embodiments of the present invention.

Referring to FIG. 2, the computational control unit 19 of the sequence adjustment unit 15 checks through the monitoring unit 17 whether either the first transfer module 13a or the second transfer module 13b is idle as there are no substrates waiting to be transferred (step S21). If it is confirmed that there is any idle transfer module, the computational control unit 19 of the sequence adjustment unit 15 checks through the monitoring unit 17 whether it is possible to input the third substrate into the idle transfer module (step S23). If, as a result of the check, the third substrate can be fed into the playing transfer module, the computational control unit 19 of the sequence adjustment unit 15 may adjust the process sequence so that the queuing and transferring of the third substrate to the idle transfer module is prioritized (step S25).

As such, in performing queuing and transferring of substrates to the processing module 11 using the transfer module 13, the substrate processing apparatus 100 may monitor the availability or workability of the process equipment (transfer module 11 and/or processing module 13) periodically or as events occur, not following a predetermined order according to a process flow recipe. Based on the monitored availability, the queuing and transferring jobs of the substrates in the transfer module unit 13 can be reordered. By allowing the substrates to be transferred to the corresponding processing module 11 according to the adjusted order of jobs, the downtime of the process equipment can be minimized and the process equipment can be operated at maximum capacity.

Referring to FIGS. 3A and 3B, it is illustrated that the process sequence in the first transfer module 13a is such that, for example, after finishing queuing and transferring the two first substrates 31 to the first processing module 11a, the third substrate 35 is subsequently queued and transferred to the first processing module 11a. At this time, the second transfer module 13b may be empty with no substrate to transfer. Furthermore, the third substrate 35 may be required to be processed not only in the first processing module 11a, but also in the second processing module 13b. In such a case, the computational control unit 19 of the sequence adjustment unit 15 monitors the status of the first and second transfer modules 13a, 13b through the monitoring unit 17 and checks whether the second transfer module 13b is idle (empty) because there is no substrate to be processed. If it is determined that the second transfer module 13b is idling, the process sequence may be adjusted to allow the third substrate 35, which is waiting to be transferred from the first transfer module 13a to the first processing module 11a, to be queued at the second transfer module 13b and transferred to the second processing module 11b (see FIG. 3A). By this adjustment of the process sequence, the third substrate 35 can be put into the process sooner than before the adjustment of the process sequence, without causing a delay in the process of the first substrates 31. In other words, this adjustment of the process sequence results in a higher utilization of the second transfer module 13b and the second processing module 11b.

Furthermore, when the process is performed in accordance with the above-mentioned adjusted process sequence, the sequence adjustment unit 15 may monitor that the queuing and transfer of the first substrate 31 to the first processing module 11a by the first transfer module 13a is terminated, and that the queuing and transfer of the third substrate 35 to the second processing module 11b by the second transfer module 13b is completed. If, as a result of monitoring, the first transfer module 13a is found to be empty with no substrate to be transferred (see FIG. 3B), the sequence adjustment unit 15 may adjust the process sequence so that the queuing and transfer of the third substrate 35 from the first transfer module 13a can be carried out in order to perform the process in the first processing module 11a for the third substrate 35.

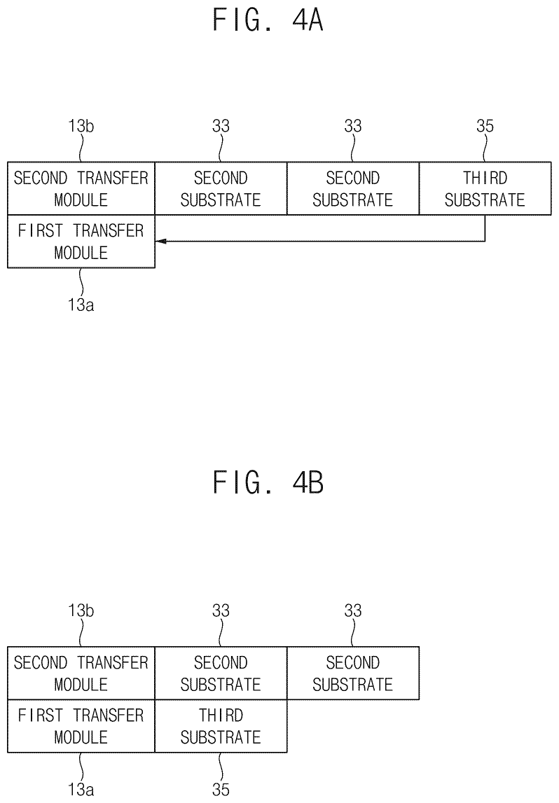

Referring to FIGS. 4A and 4B, it is illustrated that the predetermined process sequence in the second transfer module 13b is scheduled such that after finishing the queuing and transfer of two second substrates 33 to the second processing module 11b, the third substrate 35 is scheduled subsequently to be queued and transferred to the second processing module 11b. In this case, the first transfer module 13a may be in an empty state with no waiting substrates. However, the third substrate 35 may be one that is to be processed not only in the second processing module 11b, but also in the first processing module 11a. Accordingly, the computational control unit 19 of the sequence adjustment unit 15 may check whether the first transfer module 13a is empty through the monitoring unit 17. If it is confirmed to be empty, the computational control unit 19 may adjust the process order of the third substrate 35 that is scheduled to be transferred to the second transfer module 13b so that the third substrate 35 that is queued in the first transfer module 13a can be preferentially transferred to the first processing module 11a (see FIG. 4A).

Further, after the jobs are initiated according to the adjusted process sequence, the sequence adjustment unit 15 may monitor whether the queuing and transfer of the second substrate 33 to the second processing module 11b by the second transfer module 13b is completed and the queuing and transfer of the third substrate 35 to the first processing module 11a by the first transfer module 13a is completed (see FIG. 4B). If such a state is confirmed, the sequence adjustment unit 15 may monitor whether the second transfer module 13b is empty and, if the second transfer module 13b is found to be empty, may adjust the process sequence to allow the third substrate 35 to be queued in the second transfer module 13b and transferred to the second processing module 11b. Such flexible adjustment of the process sequence may allow for higher utilization of the process equipment.

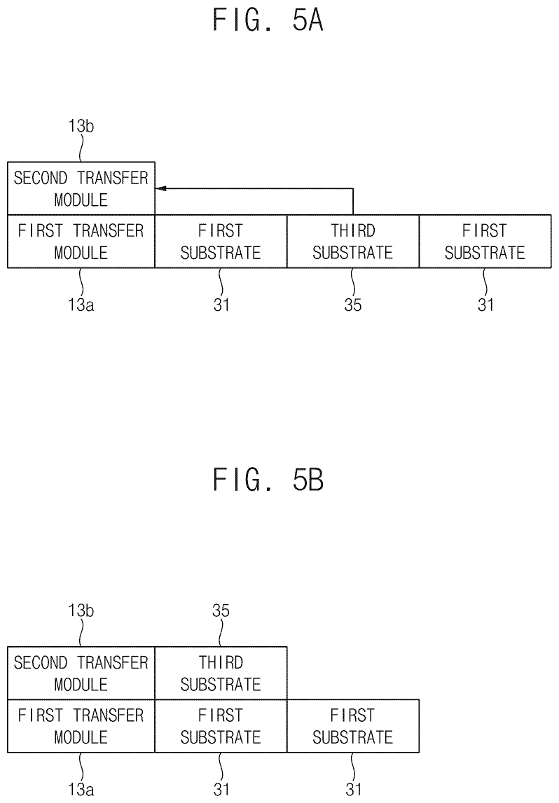

Referring to FIGS. 5A and 5B, an example is illustrated in which the queuing in the first transfer module 13a and the transferring to the first processing module 11a by the first transfer module 13a are scheduled to be performed sequentially in the order of the first substrate 31, the third substrate 35, and then the first substrate 31 again according to a predetermined process sequence (see FIG. 5A). In this case, the second transfer module 13b may be in an empty state. Accordingly, the sequence adjustment unit 15 may check to see if the second transfer module 13b is empty and, if it is found to be empty, adjust the process sequence so that the third substrate 35, which is waiting to be fed into the first processing module 11a, may be transferred from the second transfer module 13b to the second processing module 11b (see FIG. 5B).

Then, the sequence adjustment unit 15 may check whether the queuing of the two first substrates 31 in the first transfer module 13a and the transfer to the first processing module 11a is finished, and whether the waiting of the third substrate 35 in the second transfer module 13b and the transfer to the second processing module 11b is finished, and whether the first transfer module 13a is empty. If all of these checks are yes, the sequence adjustment unit 15 may adjust the process sequence such that the third substrate 35 waits in the first transfer module 13a and is transferred to the first processing module 11a (see FIG. 5B). According to this adjustment of the process sequence, the processing of the third substrate 35 may be carried out more quickly than before the adjustment of the process sequence, and the waiting time of the 2^{nd} first substrate 31 may be reduced.

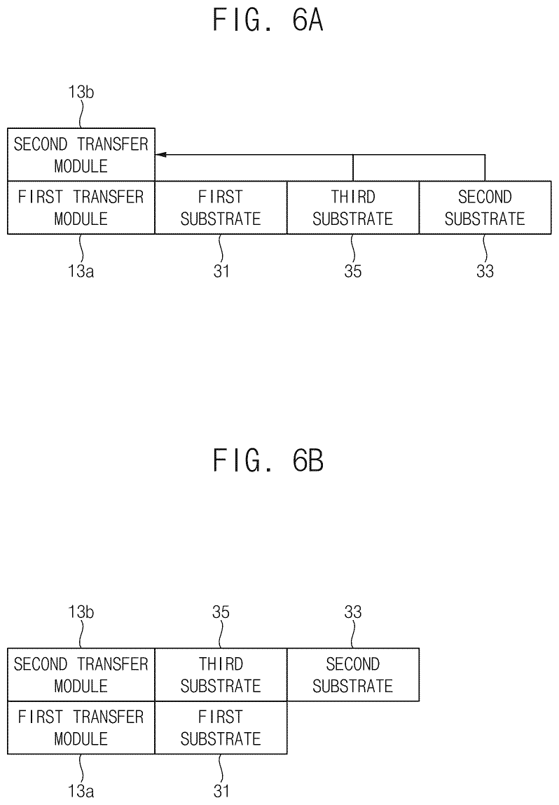

Referring to FIGS. 6A and 6B, an example is illustrated in which the queuing in the first transfer module 13a and the transferring to the first processing module 11a by the first transfer module 13a are scheduled to be performed sequentially in the order of the first substrate 31, the third substrate 35, and then the second substrate 31 again according to a predetermined process sequence. In this case, the second transfer module 13b may be in an empty state. Therefore, the computational control unit 19 of the sequence adjustment unit 15 may monitor the state of the first and second transfer modules 13a, 13b through the monitoring unit 17 to check whether the second transfer module 13b is empty, and if the second transfer module 13b is empty, may adjust the process sequence so that the third substrate 35, which is scheduled to be transferred into the first processing module 11a, can wait in the second transfer module 13b and be transferred to the second processing module 11b. As a result, the third substrate 35 can be repositioned to be queued at the second transfer module 13b according to the adjusted process sequence accordingly.

Continuing, the sequence adjustment unit 15 determines that the queuing of the first substrate 31 in the first transfer module 13a and its transfer to the first processing module 11a has ended, and that the queuing of the third substrate 35 in the second transfer module 13b and its transfer to the second processing module 13b has ended, the sequence adjustment unit 15 may rearrange the process sequence to allow the queuing of the third substrate 35 in the first transfer module 13a and its transfer to the first processing module 11a to be performed, while allowing the queuing of the second substrate 33 in the second transfer module 13b and its transfer to the second processing module 11b to be performed.

Alternatively, although not shown in the drawing, the jobs in the second transfer module 13b may be scheduled such that the queuing of the substrates in the second transfer module 13b and their transfer to the second processing module 11b are sequential, for example, in the order of the second substrate 33, the third substrate 35, and the first substrate 31. The first transfer module 13a may be empty. In this case, the sequence adjustment unit 15 may check to see if the first transfer module 13a is empty, and if it is found to be empty, may adjust the process sequence of the third substrate 35 that is scheduled to be fed into the second processing module 11b to prioritize the queuing in the first transfer module 13a and the transfer to the first processing module 11a.

Next, the sequence adjustment unit 15, after confirming through monitoring that the queuing of the second substrate 33 in the second transfer module 13b and its transfer to the second processing module 11b has ended, as well as the queuing of the third substrate 35 in the first transfer module 13a and its transfer to the first processing module 11a has ended, the sequence adjustment unit 15 may adjust the process sequence to allow the queuing of the third substrate 35 in the second transfer module 13b and its transfer to the second processing module 11b to be carried out, while also allowing the queuing of the first substrate 31 in the first transfer module 13a and its transfer to the first processing module 11a to be carried out.

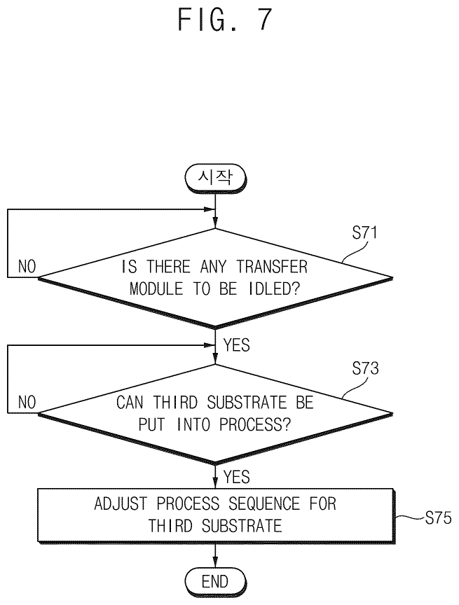

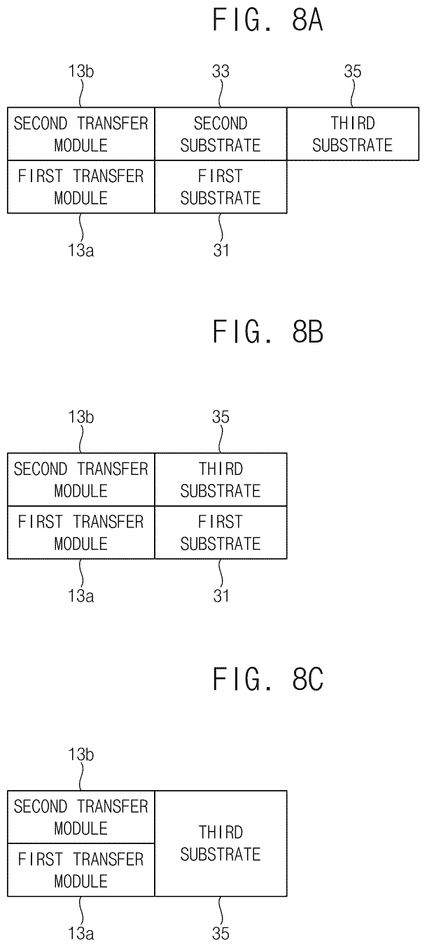

FIG. 7 illustrates a procedure for adjusting the queuing and transfer of the third substrate to prioritize it based on a check for a transfer module that is scheduled to be idle, and FIGS. 8A to 10B illustrate specific states before and after adjustments of the process sequence in the substrate processing apparatus, in accordance with exemplary embodiments of the present invention.

Referring to FIG. 7, the computational control unit 19 of the sequence adjustment unit 15 checks, through the monitoring unit 17, whether either the first transfer module 13a or the second transfer module 13b is a transfer module that is about to become idle (step S71). If it is confirmed that there is a transfer module that is about to become idle as a result of the check, the computational control unit 19 of the sequence adjustment unit 15 checks whether the third substrate 35 can be fed into the transfer module to become idle through the monitoring unit 17 (step S73). If it is confirmed that the third substrate 35 can be input to the transfer module that is about to become idle, the sequence adjustment unit 15 may adjust the process sequence so that the queuing and transfer of the third substrate 35 can be carried out preferentially in the transfer module (step S75).

Accordingly, the substrate processing apparatus 100 of the present invention may allow queuing and transferring of substrates to processing modules to be prioritized based on the order in which they can be processed, rather than in a predetermined order.

Referring to FIG. 8A, according to the pre-determined process sequence, currently the first transfer module 13a may queue and transfer the first substrate 31 to the first processing module 11a, and the second transfer module 13b may queue and transfer the second substrate 33 to the second processing module 11b, and subsequently may queue and transfer the third substrate 35 after the first transfer module 13a and/or the second transfer module 13b has finished the queuing and transferring the first substrate 31 and/or the second substrate 33. In this case, the sequence adjustment unit 15 may adjust the process sequence such that the queuing and transferring of the third substrate 35 may be prioritized by whichever of the first transfer module 13a transferring the first substrate 31 and the second transfer module 13b transferring the second substrate 33 completes the transfer operation first. That is, if it is determined that the queuing and transferring of the second substrate 33 by the second transfer module 13b is about to be finished first, as shown in FIG. 8B, the sequence adjustment unit 15 may adjust the process sequence so as to prioritize the queuing and transferring of the third substrate 35 by the second transfer module 13b. And when it is confirmed that the queuing and transferring of the first substrate 31 by the first transfer module 13a has finished, the sequence adjustment unit 15 may adjust the process sequence such that the queuing and transferring of the third substrate 35 may also be accomplished by the first transfer module 13a in conjunction with the second transfer module 13b.

Alternatively, although not shown, if it is determined that the queuing and transfer of the first substrate 31 by the first transfer module 13a is scheduled to be finished first, the sequence adjustment unit 15 may adjust the process sequence such that the queuing and transfer of the third substrate 35 by the first transfer module 13a can be carried out preferentially. And when it is confirmed that the queuing and transferring of the second substrate 33 by the second transfer module 13b has finished, the sequence adjustment unit 15 may adjust the process sequence such that the queuing and transferring of the third substrate 35 by the second transfer module 13b in conjunction with the first transfer module 13a may also be executed.

The following describes embodiments of adjusting the process sequence to prioritize the queuing and transfer of a first substrate or a second substrate that is designated as a later priority in the process sequence.

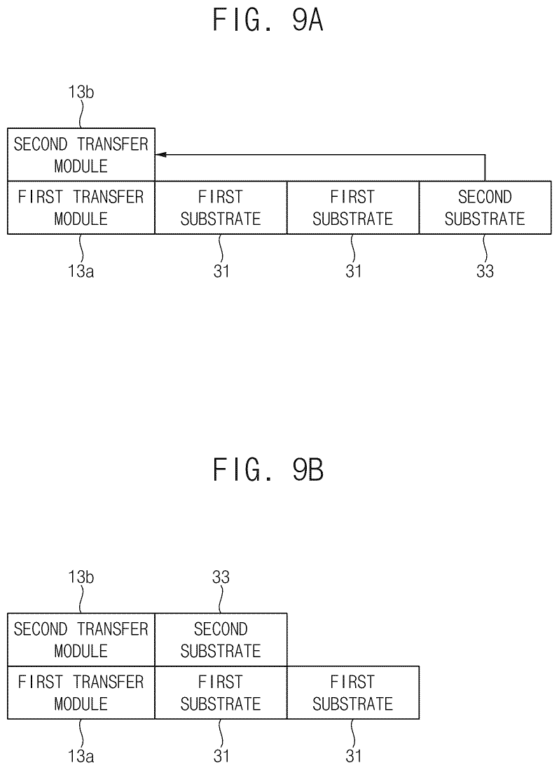

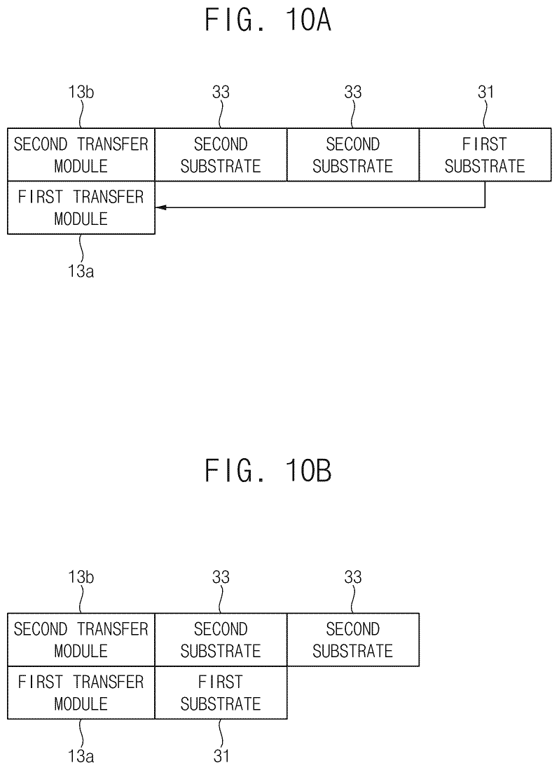

FIGS. 9A to 10B illustrates specific states before and after adjustment of the process sequence in the substrate processing apparatus, in accordance with another exemplary embodiments of the present invention.

Referring first to FIGS. 9A and 9B, the process sequence may be such that the first transfer module 13a may be in the queuing and transferring of the two first substrates 31 to the first processing module 11a, and the queuing and transferring of the second substrate 33 may be scheduled to be performed using the second transfer module 13b after the queuing and transferring of the first substrate 31 in the first transfer module 13a has ended. In other words, the process order may be such that the first substrates 31 are first and the second substrate 33 is second. In this case, the sequence adjustment unit 15 may checks whether the second transfer module 13b is currently idle (unused) or is about to be idle, and then whether the second transfer module 13b is available for queuing the second substrate 33. If yes, the sequence adjustment unit 15 may adjust the process order such that the queuing and transferring of the second substrate 33 by the second transfer module 13b is performed preferentially.

And referring to FIGS. 10A and 10B, the process sequence may be such that the second transfer module 13b may be in the queuing and transferring of the two second substrates 33 to the second processing module 11b, and the queuing and transferring of the first substrate 31 may be scheduled to be performed using the first transfer module 131 after the queuing and transferring of the second substrate 33 in the second transfer module 13a has ended. That is, the process order may be such that the second substrate 33 is first and the first substrate 31 is second. In this case, the sequence adjustment unit 15 may checks whether the first transfer module 13a is currently idle (unused) or is about to be idle, and then whether the first transfer module 13a is available for queuing the first substrate 31. If yes, the sequence adjustment unit 15 may adjust the process order such that the queuing and transferring of the first substrate 31 by the first transfer module 13a is performed preferentially.

According to the aforementioned embodiments, the substrate processing apparatus 100 according to exemplary embodiments of the present invention may be adapted to use the second transfer module 13b together with the first transfer module 13a simultaneously and efficiently, even if only the process sequence is adjusted by the sequence adjustment unit 15. In particular, since the substrate processing apparatus 100 according to exemplary embodiments of the present invention can efficiently operate both of the at least two processing modules by adjusting only the process sequence by the sequence adjustment unit 15, the operating efficiency of two or more substrate processing apparatuses can be obtained with only one substrate processing apparatus.

The substrate processing apparatus according to exemplary embodiments of the present invention is applicable to the manufacture of integrated circuit devices such as semiconductor devices, display devices, and the like, and is particularly applicable to a transfer process for transferring substrates.

While the above has been described with reference to preferred embodiments of the invention, it will be understood by those skilled in the art that various modifications and changes can be made to the invention without departing from the spirit and scope of the invention as recited in the patent claims below.

What is claimed is:

1. A substrate processing apparatus, comprising:
a processing module unit comprising at least a first processing module and a second processing module which are configured to perform different processes on substrates;
a transfer module unit comprising a first transfer module configured to queue and transfer a first substrate that can only be loaded into the first processing module, and a second transfer module configured to queue and transfer a second substrate that can only be loaded into the second processing module, wherein either the first transfer module or the second transfer module can be used to queue and transfer a third substrate that can be loaded into both the first and second processing modules; and
a sequence adjustment unit configured to adjust a process sequence according to a process flow recipe such that at least some of the first substrate, the second substrate, and the third substrate, which are junior to a substrate being processed in the process sequence, are prioritized for queuing and transferring using the first transfer module or the second transfer module that is in an idle state or about to become an idle state.

2. The substrate processing apparatus of claim 1, wherein when the process sequence according to the process flow recipe is such that the first substrate is queued and transferred first and then the second substrate is queued and transferred by the first transfer module, the sequence adjustment unit adjusts the process sequence such that the queuing and transferring of the second substrate is prioritized using the second transfer module which is in an idle state or about to become an idle state; or when the process sequence according to the process flow recipe is such that the second substrate queued and transferred first and then the first substrate is queued and transferred by the second transfer module, the sequence adjustment unit adjusts the process sequence such that the queuing and transferring of the first substrate is prioritized using the first transfer module which is in an idle state or about to become an idle state.

3. The substrate processing apparatus of claim 1, wherein when the process sequence according to the process flow recipe is such that the first substrate is queued and transferred by the first transfer module first, or the second substrate is queued and transferred by the second transfer module first, or both the first substrate and the second substrate are queued and transferred by the first transfer module and the second transfer module respectively, queuing and transferring of the third substrate is scheduled to be performed after queuing and transferring of the first substrate, the second substrate, or the first and second substrates are finished, the sequence adjustment unit adjusts the process sequence so that queuing and transferring of the third substrate can be performed preferentially using the first transfer module or the second transfer module that is in an idle state, or the first transfer module or the second transfer module that is about to become an idle state.

4. The substrate processing apparatus of claim 3, wherein when the process sequence according to the process flow recipe in the first transfer module is such that queuing and transferring of the third substrate is performed after finishing queuing and transferring of the first substrate, the sequence adjustment unit adjusts the process sequence so that queuing and transferring of the third substrate can be performed preferentially by using the second transfer module, and wherein when queuing and transferring of the first substrate is finished by the first transfer module and queuing and transferring of the third substrate is finished by the second transfer module, the sequence adjustment unit re-adjusts the process sequence so that queuing and transferring of the third substrate can be performed preferentially by using the first transfer module.

5. The substrate processing apparatus of claim 3, wherein when the process sequence according to the process flow recipe in the second transfer module is such that queuing and transferring of the third substrate is performed after finishing queuing and transferring of the second substrate, the sequence adjustment unit adjusts the process sequence so that queuing and transferring of the third substrate by using the first transfer module can be performed preferentially, and wherein when queuing and transferring of the second substrate is finished by the second transfer module and queuing and transferring of the third substrate is finished by the first transfer module, the sequence adjustment unit re-adjusts the process sequence so that queuing and transferring of the third substrate by using the second transfer module can be performed preferentially.

6. The substrate processing apparatus of claim 3, wherein when the process sequence according to the process flow recipe is such that queuing and transferring of the first substrate is performed by the first transfer module, then queuing and transferring of the third substrate and the second substrate are performed sequentially after the queuing and transferring of the first substrate is finished, the sequence adjustment unit adjusts the process sequence such that queuing and transferring of the third substrate is preferentially performed by the second transfer module; and wherein when the queuing and transferring of the first substrate is finished by the first transfer module and the queuing and transferring of the third substrate is finished by the second transfer module, the sequence adjustment unit re-adjusts the process sequence such that queuing and transferring of the third substrate can be performed by the first transfer module, and queuing and transferring of the second substrate can be performed by the second transfer module.

7. The substrate processing apparatus of claim 3, wherein when the process sequence according to the process flow recipe is such that queuing and transferring of the second substrate is performed by the second transfer module, then queuing and transferring of the third substrate and the first substrate are performed sequentially after the queuing and transferring of the second substrate is finished, the sequence adjustment unit adjusts the process sequence such that queuing and transferring of the third substrate is preferentially performed by the first transfer module; and wherein when the queuing and transferring of the second substrate is finished by the second transfer module and the queuing and transferring of the third substrate is finished by the first transfer module, the sequence adjustment unit re-adjusts the process sequence such that queuing and transferring of the third substrate can be performed by the second transfer module, and queuing and transferring of the first substrate can be performed by the first transfer module.

8. The substrate processing apparatus of claim 3, wherein when the process sequence according to the process flow recipe is such that queuing and transferring of the first substrate and the second substrate are performed by the first and second transfer module respectively first, and then queuing and transferring of the third substrate is performed after the queuing and transferring of either the first substrate or the second substrate is finished by either the first transfer module or the second transfer module, the sequence adjustment unit adjusts the process sequence so that queuing and transferring of the third substrate can be preferentially performed by any one out of the first transfer module and the second transfer module, whichever finishes the transferring first.

9. A substrate processing apparatus, comprising:
a first processing module;
a second processing module;
a transfer module unit comprising a first transfer module configured to queue and transfer a first substrate that can only be loaded into the first processing module, and a second transfer module configured to queue and transfer a second substrate that can only be loaded into the second processing module, wherein either the first transfer module or the second transfer module can be used to queue and transfer a third substrate that can be loaded into both the first and second processing modules; and
a sequence adjustment unit configured to adjust a process sequence according to a process flow recipe such that at least some of the first substrate, the second substrate, and the third substrate, which are junior to a substrate being processed in the process sequence, are prioritized for queuing and transferring using the first transfer module or the second transfer module that is in an idle state or about to become an idle state.

10. The substrate processing apparatus of claim 9, wherein when the process sequence according to the process flow recipe is such that the first substrate is queued and transferred first and then the second substrate is queued and transferred by the first transfer module, the sequence adjustment unit adjusts the process sequence such that the queuing and transferring of the second substrate is prioritized using the second transfer module which is in an idle state or about to become an idle state; or when the process sequence according to the process flow recipe is such that the second substrate queued and transferred first and then the first substrate is queued and transferred by the second transfer module, the sequence adjustment unit adjusts the process sequence such that the queuing and transferring of the first substrate is prioritized using the first transfer module which is in an idle state or about to become an idle state.

11. The substrate processing apparatus of claim 9, wherein when the process sequence according to the process flow recipe is such that the first substrate is queued and transferred by the first transfer module first, or the second substrate is queued and transferred by the second transfer module first, or both the first substrate and the second substrate are queued and transferred by the first transfer module and the second transfer module respectively, queuing and transferring of the third substrate is scheduled to be performed after queuing and transferring of the first substrate, the second substrate, or the first and second substrates are finished, the sequence adjustment unit adjusts the process sequence so that queuing and transferring of the third substrate can be performed preferentially using the first transfer module or the second transfer module that is in an idle state, or the first transfer module or the second transfer module that is about to become an idle state.

12. The substrate processing apparatus of claim 11, wherein when the process sequence according to the process flow recipe in the first transfer module is such that queuing and transferring of the third substrate is performed after finishing queuing and transferring of the first substrate, the sequence adjustment unit adjusts the process sequence so that queuing and transferring of the third substrate can be performed preferentially by using the second transfer module, and wherein when queuing and transferring of the first substrate is finished by the first transfer module and queuing and transferring of the third substrate is finished by the second transfer module, the sequence adjustment unit re-adjusts the process sequence so that queuing and transferring of the third substrate can be performed preferentially by using the first transfer module.

13. The substrate processing apparatus of claim 11, wherein when the process sequence according to the process flow recipe in the second transfer module is such that queuing and transferring of the third substrate is performed after finishing queuing and transferring of the second substrate, the sequence adjustment unit adjusts the process sequence so that queuing and transferring of the third substrate by using the first transfer module can be performed preferentially, and wherein when queuing and transferring of the second substrate is finished by the second transfer module and queuing and transferring of the third substrate is finished by the first transfer module, the sequence adjustment unit re-adjusts the process sequence so that queuing and transferring of the third substrate by using the second transfer module can be performed preferentially.

14. The substrate processing apparatus of claim 11, wherein when the process sequence according to the process flow recipe is such that queuing and transferring of the first substrate is performed by the first transfer module, then queuing and transferring of the third substrate and the second substrate are performed sequentially after the queuing and transferring of the first substrate is finished, the sequence adjustment unit adjusts the process sequence such that queuing and transferring of the third substrate is preferentially performed by the second transfer module; and wherein when the queuing and transferring of the first substrate is finished by the first transfer module and the queuing and transferring of the third substrate is finished by the second transfer module, the sequence adjustment unit re-adjusts the process sequence such that queuing and transferring of the third substrate can be performed by the first transfer module, and queuing and transferring of the second substrate can be performed by the second transfer module.

15. The substrate processing apparatus of claim 11, wherein when the process sequence according to the process flow recipe is such that queuing and transferring of the second substrate is performed by the second transfer module, then queuing and transferring of the third substrate and the first substrate are performed sequentially after the queuing and transferring of the second substrate is finished, the sequence adjustment unit adjusts the process sequence such that queuing and transferring of the third substrate is preferentially performed by the first transfer module; and wherein when the queuing and transferring of the second substrate is finished by the second transfer module and the queuing and transferring of the third substrate is finished by the first transfer module, the sequence adjustment unit re-adjusts the process sequence such that queuing and transferring of the third substrate can be performed by the second transfer module, and queuing and transferring of the first substrate can be performed by the first transfer module.

16. The substrate processing apparatus of claim 11, wherein when the process sequence according to the process flow recipe is such that queuing and transferring of the first substrate and the second substrate are performed by the first and second transfer module respectively first, and then queuing and transferring of the third substrate is performed after the queuing and transferring of either the first substrate or the second substrate is finished by either the first transfer module or the second transfer module, the sequence adjustment unit adjusts the process sequence so that queuing and transferring of the third substrate can be preferentially performed by any one out of the first transfer module and the second transfer module, whichever finishes the transferring first.

17. A substrate processing apparatus, comprising:
a first processing module configured to perform a first treatment process with first process conditions;
a second processing module configured to perform a second treatment process with second process conditions;
a transfer module unit comprising a first transfer module configured to queue and transfer a first substrate that can only be loaded into the first processing module, and a second transfer module configured to queue and transfer a second substrate that can only be loaded into the second processing module, wherein either the first transfer module or the second transfer module can be used to queue and transfer a third substrate that can be loaded into both the first and second processing modules; and
a sequence adjustment unit configured to adjust a process sequence according to a process flow recipe,
wherein when the process sequence according to the process flow recipe is such that the first substrate is queued and transferred first and then the second substrate is queued and transferred by the first transfer module, the sequence adjustment unit adjusts the process sequence such that the queuing and transferring of the second substrate is prioritized using the second transfer module which is in an idle state or about to become an idle state; or when the process sequence according to the process flow recipe is such that the second substrate queued and transferred first and then the first substrate is queued and transferred by the second transfer module, the sequence adjustment unit adjusts the process sequence such that the queuing and transferring of the first substrate is prioritized using the first transfer module which is in an idle state or about to become an idle state; or
wherein when the process sequence according to the process flow recipe is such that the first substrate is queued and transferred by the first transfer module first, or the second substrate is queued and transferred by the second transfer module first, or both the first substrate and the second substrate are queued and transferred by the first transfer module and the second transfer module respectively, queuing and transferring of the third substrate is scheduled to be performed after queuing and transferring of the first substrate, the second substrate, or the first and second substrates are finished, the sequence adjustment unit adjusts the process sequence so that queuing and transferring of the third substrate can be performed preferentially using the first transfer module or the second transfer module that is in an idle state, or the first transfer module or the second transfer module that is about to become an idle state.

18. The substrate processing apparatus of claim 17, wherein the first processing module is configured to perform a first baking process on the first substrate or the third substrate at a first temperature condition, and the second processing module is configured to perform a second baking process on the second substrate or the third substrate at a second temperature condition.

19. The substrate processing apparatus of claim 17, wherein the sequence adjustment unit adjusts the process sequence so that when the third substrate is subsequently queued and transferred by the first transfer module, the queuing and transferring of the third substrate can be preferentially performed by the second transfer module, and when the third substrate is subsequently queued and transferred by the second transfer module, the queuing and transferring of the third substrate can be preferentially performed by the first transfer module.

20. The substrate processing apparatus of claim 17, wherein when queuing and transferring of the first substrate is performed by the first transfer module and queuing and transferring of the second substrate is performed by the second transfer module, and the third substrate is subsequently queued in either the first transfer module or the second transfer module, the sequence adjustment unit adjusts the process sequence so that queuing and transferring of the third substrate can be performed by the first transfer module or the second transfer module, whichever finishes the queuing and transferring first.
